(19) United States
(12) Patent Application Publication
(10) Pub. No.: US 2025/0357951 A1
(43) Pub. Date: Nov. 20, 2025

(54) DECODING OF LOW-DENSITY PARITY CHECK CODES

(71) Applicant: Samsung Electronics Co., Ltd., Suwon-si (KR)

(72) Inventors: Heping Wan, Plano, TX (US); Joonyoung Cho, Portland, OR (US); Min Jang, Suwon-si (KR)

(21) Appl. No.: 19/070,315

(22) Filed: Mar. 4, 2025

Related U.S. Application Data
(60) Provisional application No. 63/648,479, filed on May 16, 2024.

(51) Int. Cl. H03M 13/11; H04L 1/00

(52) U.S. Cl. CPC H03M 13/1125; H04L 1/0057

(57) ABSTRACT

Decoding low-density parity check (LDPC) codes in a communication system includes identifying a first set of indices of variable nodes (VNs) having log-likelihood ratios (LLRs) greater than a threshold. A second set of indices that includes the first set of indices, indices of shortening VNs, and indices of single parity check (SPC) VNs is created. LDPC decoding proceeds by iteratively updating check-to-variable (C2V) messages and variable-to-check (V2C) messages, with updates for a VN being skipped when an index of the respective VN belongs to the second set of indices.

### CROSS-REFERENCE TO RELATED AND CLAIM OF PRIORITY

The present application claims priority under 35 U.S.C. § 119(e) to U.S. Provisional Patent Application No. 63/648,479 filed on May 16, 2024, which is hereby incorporated by reference in its entirety.

### TECHNICAL FIELD

The present disclosure relates generally to low density parity check codes and, more specifically, to improving throughput with low density parity check codes with acceptable error rate loss.

### BACKGROUND

Wireless communication has been one of the most successful innovations in modern history. Recently, the number of subscribers to wireless communication services exceeded five billion and continues to grow quickly. The demand of wireless data traffic is rapidly increasing due to the growing popularity among consumers and businesses of smart phones and other mobile data devices, such as tablets, “note pad” computers, net books, eBook readers, and machine type of devices. In order to meet the high growth in mobile data traffic and support new applications and deployments, improvements in radio interface efficiency and coverage are of paramount importance. To meet the demand for wireless data traffic having increased since deployment of 4G communication systems, and to enable various vertical applications, 5G communication systems have been developed and are currently being deployed.

### SUMMARY

The present disclosure relates to selectively skipping messages during decoding of low density parity check codes.

In a first embodiment, a method for decoding low-density parity check (LDPC) codes in a communication system includes identifying a first set of indices of variable nodes (VNs) having log-likelihood ratios (LLRs) greater than a threshold. The method also includes creating a second set of indices that includes the first set of indices, indices of shortening VNs, and indices of single parity check (SPC) VNs. The method further includes performing LDPC decoding by iteratively updating check-to-variable (C2V) messages and variable-to-check (V2C) messages, with updates for a VN being skipped when an index of the respective VN belongs to the second set of indices.

In a second embodiment, an apparatus for decoding low-density parity check (LDPC) codes in a communication system includes a transceiver configured to receive a signal having an associated LDPC code and at least one processor coupled to the transceiver and configured to decode the LDPC code. The processor decoded LDPC code by identifying a first set of indices of variable nodes (VNs) having log-likelihood ratios (LLRs) greater than a threshold. The processor also decodes the LDPC code by creating a second set of indices that includes the first set of indices, indices of shortening VNs, and indices of single parity check (SPC) VNs. The processor further decodes the LDPC code by iteratively updating check-to-variable (C2V) messages and variable-to-check (V2C) messages, with updates for a VN being skipped when an index of the respective VN belongs to the second set of indices.

In a third embodiment, a non-transitory machine readable medium includes instructions that, when executed by at least one processor of an electronic device, cause the electronic device to identify a first set of indices of variable nodes (VNs) having log-likelihood ratios (LLRs) greater than a threshold. The instructions, when executed by the at least one processor of the electronic device, also cause the electronic device to create a second set of indices that includes the first set of indices, indices of shortening VNs, and indices of single parity check (SPC) VNs. The instructions, when executed by the at least one processor of the electronic device, also cause the electronic device to perform low-density parity check (LDPC) decoding by iteratively updating check-to-variable (C2V) messages and variable-to-check (V2C) messages, with updates for a VN being skipped when an index of the respective VN belongs to the second set of indices.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network within which decoding of low-density parity check codes may be implemented according to embodiments of the present disclosure;

FIG. 2 illustrates an example gNB within which decoding of low-density parity check codes may be implemented according to embodiments of the present disclosure;

FIG. 3 illustrates an example UE within which decoding of low-density parity check codes may be implemented according to embodiments of the present disclosure;

FIG. 4A and FIG. 4B illustrate an example of wireless transmit and receive paths, respectively, within the gNB of FIG. 2 and/or the UE of FIG. 3;

FIG. 5 illustrates a flowchart of an example procedure for decoding of low-density parity check codes according to embodiments of the present disclosure;

FIG. 6 illustrates a diagram of an example of a constellation and labeling rule of modulation for use with decoding of low-density parity check codes according to embodiments of the present disclosure;

FIG. 7 is a flowchart of an example procedure for decoding of low-density parity check codes according to embodiments of the present disclosure;

FIG. 8 is a flowchart of an example procedure for identifying a set of indices of variable nodes according to embodiments of the present disclosure;

FIG. 9 is a flowchart of an example procedure for check-node processing according to embodiments of the present disclosure;

FIG. 10 is a flowchart of an example procedure for generating a threshold according to embodiments of the present disclosure;

FIG. 11 is a flowchart of an example procedure for a single LDPC decoding iteration with flooding schedule according to embodiments of the present disclosure;

FIGS. 12A through 12C illustrate comparisons between decoding of low-density parity check codes without and with skipping the update of some messages in accordance with the present disclosure, in terms of block error rate (BLER), complexity, and average number of iterations;

FIG. 13 shows pseudo-code for SW-LDEC with VN deactivation during decoding of low-density parity check codes in accordance with the present disclosure;

FIG. 14 is a Tanner graph representing an LDPC code, and FIGS. 14A and 14B emphasize portions of the Tanner graph of FIG. 14 with indications reflecting V2C messages and C2V messages, respectively; and

FIG. 15 is pseudo-code for a layer-scheduled LDPC decoding algorithm.

### DETAILED DESCRIPTION

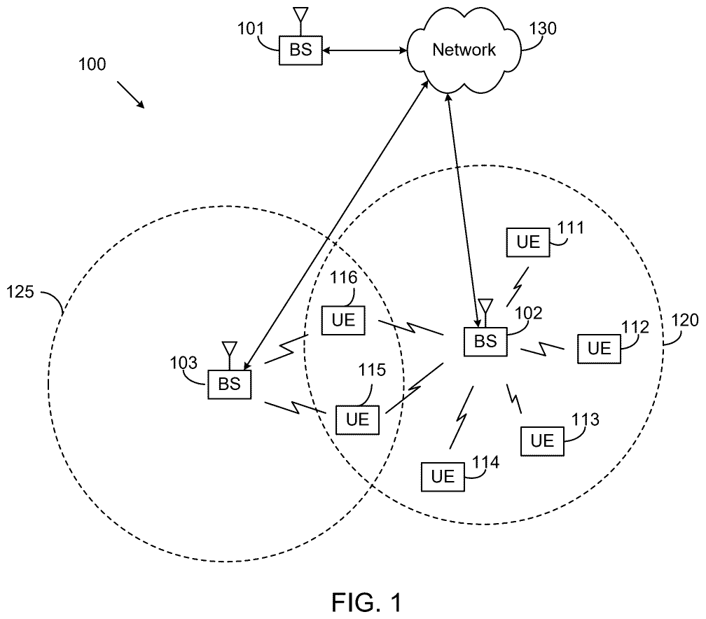

FIGS. 1-13, discussed below, and the various, non-limiting embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

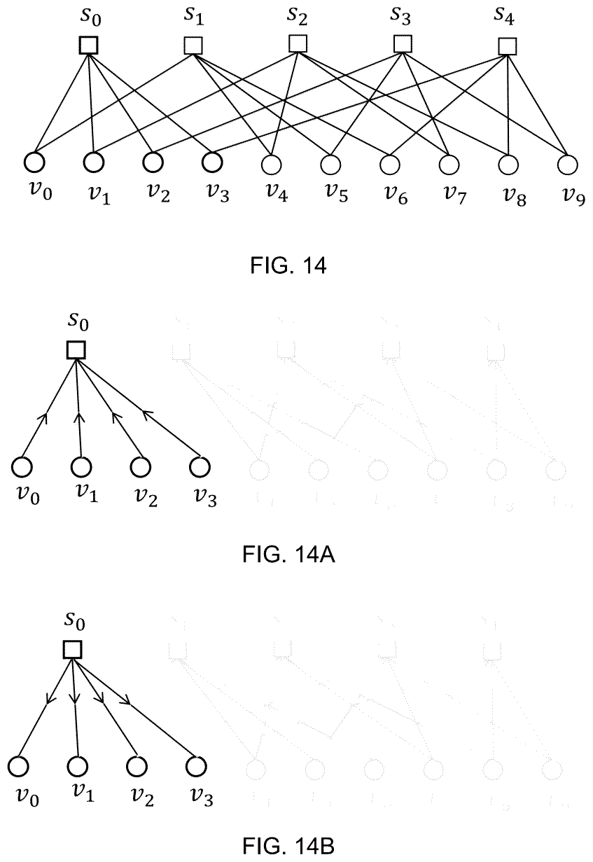

Low-density parity-check (LDPC) codes have been widely applied to wireless communications because LDPC codes are able to approach channel capacity asymptotically using belief propagation (BP) decoding. A LDPC code of dimension K and length N is defined with a (N−K)×N parity check matrix (PCM) H, where each row and each column correspond to a check equation and a codeword bit, respectively. Denote h_{j,i}∈{0,1} the element in j-th row and i-th column of PCM, where j∈{0, 1, . . . , N−K−1} and i∈{0, 1, . . . , N−1}. As shown in FIG. 14, LDPC codes can also be represented by the Tanner graph, which is composed of two types of nodes: a variable node (VN), which corresponds to a codeword bit; and a check node (CN), which corresponds to a parity check equation (i.e., the values of the bits connects to the same CN sum up to zero). A valid LDPC codeword must satisfy all parity check equations s. VNs and CNs are connected at the edges thereof, and a CN and a VN are neighbors whenever those nodes are connected. VN i, denoted vᵢ in FIG. 14, is connected to CN j, denoted sⱼ, whenever the parity check matrix element h_{j,i}=1. Accordingly, there are (N−K) CNs in a Tanner graph, one for each check equation s, and N VNs, one for each codeword bit. Therefore, in the sequel, v; is used to represent ith VN or ith codeword bit.

Messages between nodes are iteratively updated in the Tanner graph. The a posteriori log-likelihood ratio (AP-LLR) at VN i is given by

$${λ}_{i} = log ( \frac{= 0 \vert {y}_{i} )}{= 1 \vert {y}_{i} )} ) ,$$

where P is a probability and yᵢ is a received symbol. The V2C message α_{i→j} is the message passed from VN i to CN j. The C2V message β_{j→i} is the message passed from CN j to VN i. Other notations include: Vⱼ{VN indices connected to CN j}, e.g., V₀=[0:3]; V_{j\i}={VN indices connected to CN j}−{i}, e.g., V_{0\2}={0,1,3}; [symbol] ⱼ={CN indices connected to VN i}, e.g., [symbol] ₁={0,2}; and [symbol] _{i\j}={CN indices connected to VN i}−{j}, e.g., [symbol] _{1\0}={2}.

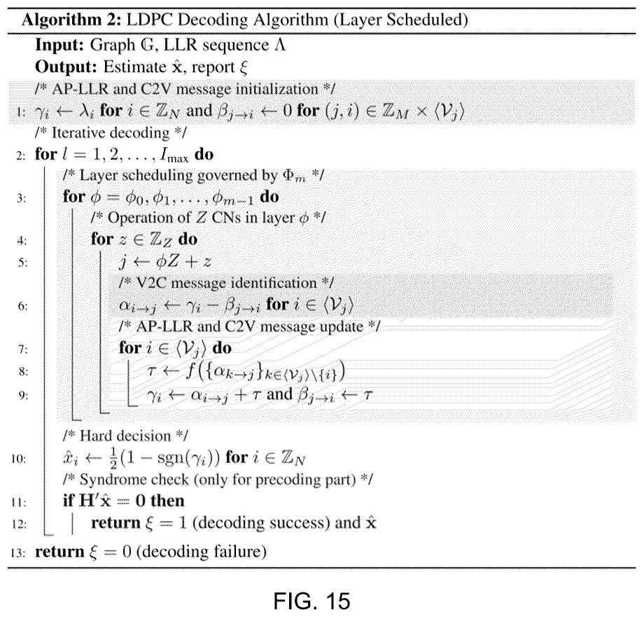

FIGS. 14A and 14B illustrate elementary CN processing in a layered decoder (LDEC). For CN j and the set Vⱼ of VNs connected to CN j, processing is composed of two stages: First, identification of V2C messages (illustrated in FIG. 14A) occurs, with α_{i→j}=γᵢ−β_{j→i} for i∈Vⱼ, where γᵢ is determined as indicated below. Second, C2V messages (illustrated in FIG. 14B) and AP-LLR messages are updated using

$${β}_{j \to i} ← {\prod }_{{i}^{′} ∈ {j \backslash i}_{}} sgn ( {α}_{{i}^{′} \to j} ) \times f ( \{ \vert {α}_{{i}^{′} \to j} \vert : {i}^{′} ∈ {j ∖ i}_{} \} )$$

$$and$$

$${γ}_{i} ← {α}_{i \to j} + {β}_{j \to i} .$$

where i′ is an index and sgn is a sign function that has a value of −1, +1, or 0. Pseudo-code for a layer-scheduled LDPC decoding algorithm is shown in FIG. 15. In the algorithm shown, CNs are processed in a sequential order for multiple iterations. Notations used in the pseudo-code that were not explained above are: A denotes initial LLRs from channel observations; ¢ denotes a layer (with a layer in LDEC potentially containing multiple CNs and with CNs in the same layer being processed in parallel); and Iₘₐₓ denotes the maximum number of iterations.

LDPC codes are currently used for 5G/NR data channels and will (in high probability) continue to be used in future cellular systems. However, channel decoding is one of the most time-consuming procedures, making improvement of the throughput an LDPC decoder (and therefore the throughput of cellular systems) important.

To implement LDPC in practical communication systems, the complexity of LDPC codes should be reduced to improve throughput. For a software-implemented layered decoder (SW-LDEC), the present disclosure seeks to double throughput with acceptable error rate loss.

Special VNs related only to LDPC code design in the present disclosure include: the single parity check (SPC) VN, a VN which only connects to one CN; and the shortening VN, a VN always assigned with zero (which, since this knowledge is known by the decoder, allows the corresponding LLR to be initialized to +00).

The following documents and standards descriptions are hereby incorporated by reference into the present disclosure as if fully set forth herein:
[1] Hocevar, Dale E. “A reduced complexity decoder architecture via layered decoding of LDPC codes.” IEEE Workshop onSignal Processing Systems, 2004.
[2] Jang, Min, et al. “Analysis and design of QC-LDPC coded BICM ensembles based on RCA density evolution.” IEEE Transactions on Communications 70.4 (2022): 2183-2199.

The present disclosure aims to reduce the complexity of LDPC decoding by skipping the update of some messages.

BP decoding is mainly composed of two stages: variable-to-check (V2C) message update and check-to-variable (C2V) message update. The message exchanged between VN and CN can be log likelihood ratio (LLR) which is defined as the logarithm of the probability of a bit being 0 divided by the probability of the bit being 1. In the V2C stage, VN vᵢ passes a message to a neighboring CN cⱼ based on the messages from channel observation and all neighboring CNs, excluding the message from CN cⱼ. In the C2V stage, CN cⱼ passes a message to a neighboring VN vᵢ based on the messages from all of its neighboring VNs, excluding the message from VN vᵢ. The V2C stage and the C2V stage are performed cooperatively and iteratively until the decoding converges or a stopping criterion is met.

Conventionally, BP decoding is equipped with flooding schedule where all VNs are processed in parallel in the V2C stage and all CNs are processed in parallel in the C2V stage. However, the flooding schedule requires multiple iterations to achieve a target block error rate (BLER) due to its low convergence speed.

To reduce the number of iterations, sequential processing can be employed. For example, in layered decoding [1], CNs are processed in a given order instead of in parallel. The sequential processing ensures that the latest messages due to the processing of previous CNs can be immediately employed to update the messages corresponding to next CN.

FIGS. 1-4 below describe various embodiments implemented in wireless communications systems and with the use of orthogonal frequency division multiplexing (OFDM) or orthogonal frequency division multiple access (OFDMA) communication techniques. The descriptions of FIGS. 1-4 are not meant to imply physical or architectural limitations to how different embodiments may be implemented. Different embodiments of the present disclosure may be implemented in any suitably arranged communications system.

FIG. 1 illustrates an example wireless network 100 within which decoding of low-density parity check codes may be implemented according to embodiments of the present disclosure. The embodiment of the wireless network 100 shown in FIG. 1 is for illustration only. Other embodiments of the wireless network 100 could be used without departing from the scope of this disclosure.

As shown in FIG. 1, the wireless network 100 includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

The dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

As described in more detail below, one or more of the UEs 111-116 include circuitry, programing, or a combination thereof for decoding of low-density parity check codes. In certain embodiments, one or more of the BSs 101-103 include circuitry, programing, or a combination thereof to support decoding of low-density parity check codes.

Although FIG. 1 illustrates one example of a wireless network, various changes may be made to FIG. 1. For example, the wireless network 100 could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

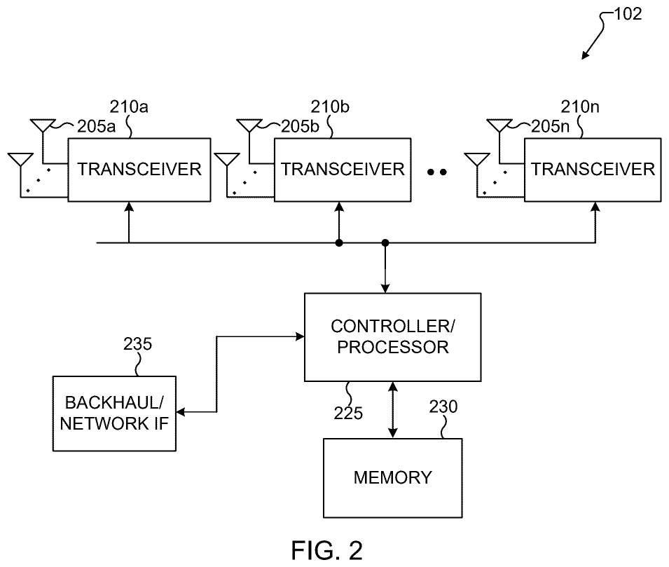

FIG. 2 illustrates an example gNB 102 within which decoding of low-density parity check codes may be implemented according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming radio frequency (RF) signals, such as signals transmitted by UEs in the wireless network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of uplink (UL) channel signals and the transmission of downlink (DL) channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. As another example, the controller/processor 225 could support methods for beam management in JPTA system with multiple component carriers. Any of a wide variety of other functions could be supported in the gNB 102 by the controller/processor 225.

The controller/processor 225 is also capable of executing programs and other processes resident in the memory 230, such as processes to trigger beam management in JPTA system with multiple component carriers. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

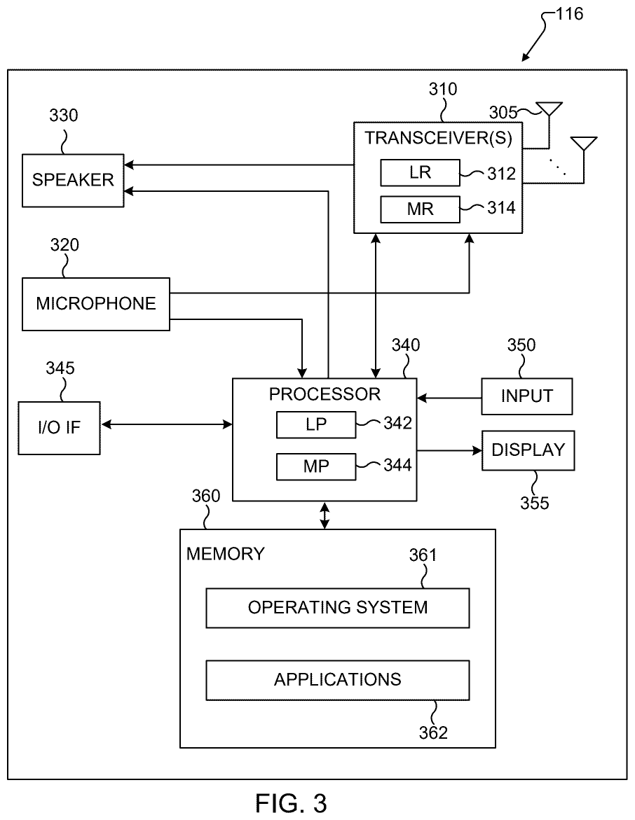

FIG. 3 illustrates an example UE 116 within which decoding of low-density parity check codes may be implemented according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives from the antenna(s) 305, an incoming RF signal transmitted by a gNB of the wireless network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. For example, the processor 340 may execute processes for beam management in JPTA system with multiple component carriers as described in embodiments of the present disclosure. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes, for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

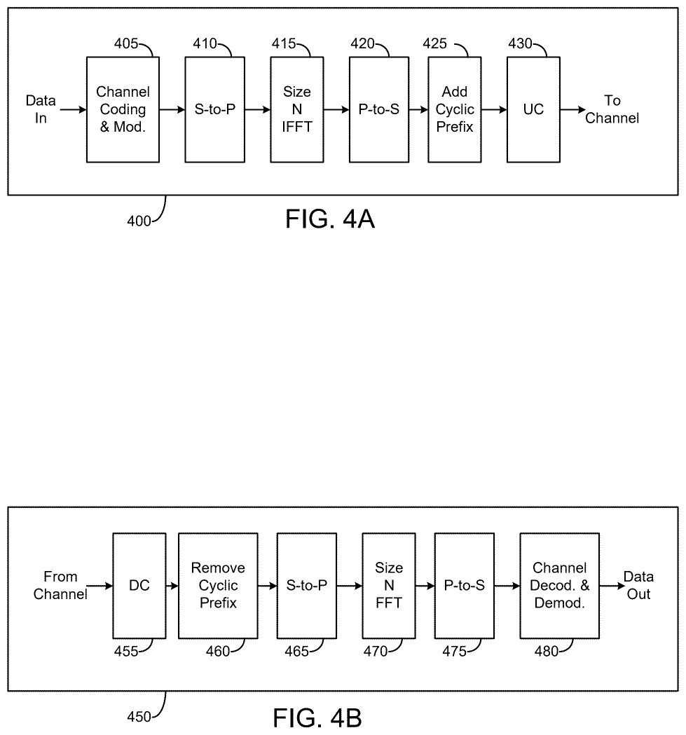

FIG. 4A and FIG. 4B illustrate an example of wireless transmit and receive paths 400 and 450, respectively, according to embodiments of the present disclosure. For example, a transmit path 400 may be described as being implemented in a gNB (such as gNB 102), while a receive path 450 may be described as being implemented in a UE (such as UE 116). However, it will be understood that the receive path 450 can be implemented in a gNB and that the transmit path 400 can be implemented in a UE. In some embodiments, the receive path 450 is configured for decoding of low-density parity check codes as described in embodiments of the present disclosure. For example, embodiments of decoding of low-density parity check codes as described herein may be implemented in connection with channel decoding and demodulation 480 depicted in FIG. 4B.

As illustrated in FIG. 4A, the transmit path 400 includes a channel coding and modulation block 405, a serial-to-parallel (S-to-P) block 410, a size N Inverse Fast Fourier Transform (IFFT) block 415, a parallel-to-serial (P-to-S) block 420, an add cyclic prefix block 425, and an up-converter (UC) 430. The receive path 450 includes a down-converter (DC) 455, a remove cyclic prefix block 460, a S-to-P block 465, a size N Fast Fourier Transform (FFT) block 470, a parallel-to-serial (P-to-S) block 475, and a channel decoding and demodulation block 480.

In the transmit path 400, the channel coding and modulation block 405 receives a set of information bits, applies coding (such as a low-density parity check (LDPC) coding), and modulates the input bits (such as with Quadrature Phase Shift Keying (QPSK) or Quadrature Amplitude Modulation (QAM)) to generate a sequence of frequency-domain modulation symbols. The serial-to-parallel block 410 converts (such as de-multiplexes) the serial modulated symbols to parallel data in order to generate N parallel symbol streams, where N is the IFFT/FFT size used in the gNB 102 and the UE 116. The size N IFFT block 415 performs an IFFT operation on the N parallel symbol streams to generate time-domain output signals. The parallel-to-serial block 420 converts (such as multiplexes) the parallel time-domain output symbols from the size N IFFT block 415 in order to generate a serial time-domain signal. The add cyclic prefix block 425 inserts a cyclic prefix to the time-domain signal. The up-converter 430 modulates (such as up-converts) the output of the add cyclic prefix block 425 to a RF frequency for transmission via a wireless channel. The signal may also be filtered at a baseband before conversion to the RF frequency.

As illustrated in FIG. 4B, the down-converter 455 down-converts the received signal to a baseband frequency, and the remove cyclic prefix block 460 removes the cyclic prefix to generate a serial time-domain baseband signal. The serial-to-parallel block 465 converts the time-domain baseband signal to parallel time-domain signals. The size N FFT block 470 performs an FFT algorithm to generate N parallel frequency-domain signals. The (P-to-S) block 475 converts the parallel frequency-domain signals to a sequence of modulated data symbols. The channel decoding and demodulation block 480 demodulates and decodes the modulated symbols to recover the original input data stream.

Each of the gNBs 101-103 may implement a transmit path 400 that is analogous to transmitting in the downlink to UEs 111-116 and may implement a receive path 450 that is analogous to receiving in the uplink from UEs 111-116. Similarly, each of UEs 111-116 may implement a transmit path 400 for transmitting in the uplink to gNBs 101-103 and may implement a receive path 450 for receiving in the downlink from gNBs 101-103.

Each of the components in FIGS. 4A and 4B can be implemented using only hardware or using a combination of hardware and software/firmware. As a particular example, at least some of the components in FIGS. 4A and 4B may be implemented in software, while other components may be implemented by configurable hardware or a mixture of software and configurable hardware. For instance, the FFT block 470 and the IFFT block 415 may be implemented as configurable software algorithms, where the value of size N may be modified according to the implementation.

Furthermore, although described as using FFT and IFFT, this is by way of illustration only and should not be construed to limit the scope of the present disclosure. Other types of transforms, such as Discrete Fourier Transform (DFT) and Inverse Discrete Fourier Transform (IDFT) functions, can be used. It will be appreciated that the value of the variable N may be any integer number (such as 1, 2, 3, 4, or the like) for DFT and IDFT functions, while the value of the variable N may be any integer number that is a power of two (such as 1, 2, 4, 8, 16, or the like) for FFT and IFFT functions.

Although FIGS. 4A and 4B illustrate examples of wireless transmit and receive paths 400 and 450, respectively, various changes may be made to FIGS. 4A and 4B. For example, various components in FIGS. 4A and 4B can be combined, further subdivided, or omitted and additional components can be added according to particular needs. Also, FIGS. 4A and 4B are meant to illustrate examples of the types of transmit and receive paths that can be used in a wireless network. Any other suitable architectures can be used to support wireless communications in a wireless network.

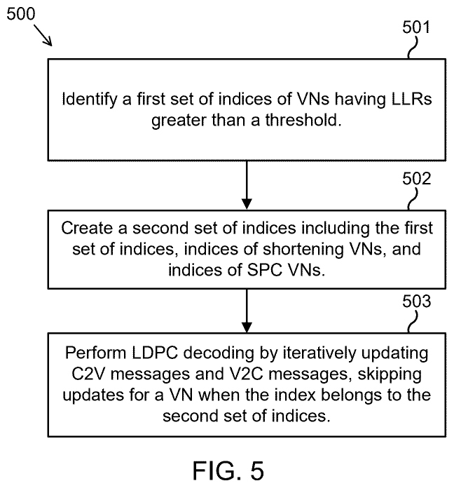

FIG. 5 illustrates a flowchart of an example procedure 500 for decoding of low-density parity check codes according to embodiments of the present disclosure. For example, procedure 600 for decoding of low-density parity check codes can be performed by the UE 116, the gNB 102, and/or network 130 in the wireless network 100 of FIG. 1. This example is for illustration only and other embodiments can be used without departing from the scope of the present disclosure.

The procedure 500 begins with identifying a first set of indices of VNs that have LLRs greater than a threshold (step 501). For example, the threshold may correspond to bit levels with the highest reliability based on mutual information between bit levels and a received signal. Probability density functions (PDFs) of LLRs may be generated for the determined bit levels, then used to incrementally increase a threshold value initialized to zero based on an average number of bits assigned to the determined bit levels with LLRs larger than the threshold and a probability of at least one bit being incorrectly recovered. A second set of indices is created (step 502), including the first set of indices, indices of shortening VNs, and indices of SPC VNs. As noted above, shortening VN are always assigned with zero, allowing the corresponding LLR to be initialized to +∞, while SPC VNs only connect to one CN. LDPC decoding is then performed by iteratively updating C2V messages and V2C messages (step 503), skipping updates for any VN when the index of that VN belongs to the second set of indices.

Although FIG. 5 illustrates one example of a process 500 for decoding of low-density parity check codes, various changes may be made to FIG. 5. For example, while shown as a series of steps, various steps in FIG. 5 could overlap, occur in parallel, occur in a different order, or occur any number of times (including zero times).

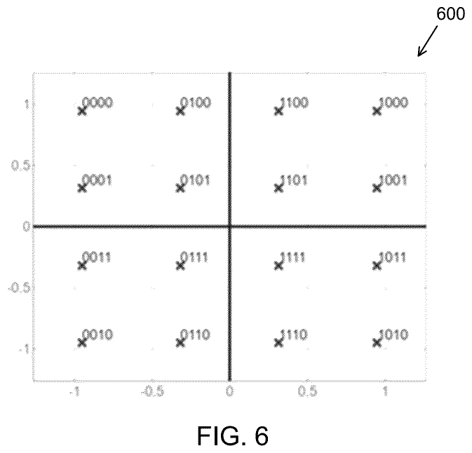

FIG. 6 illustrates a diagram of an example 600 of a constellation and labeling rule of modulation for use with decoding of low-density parity check codes according to embodiments of the present disclosure. For example, the example 600 can be implemented by any of the UEs 111-116 of FIG. 1, such as the UE 111. This example is for illustration only and other embodiments can be used without departing from the scope of the present disclosure.

In communication systems, modulation is an essential technique used to improve spectral efficiency. Modulation is defined by the example 600 with a one-to-one labeling function which maps m bits {bₗ: l=0, 1, . . . , m−1} to a constellation comprising 2^{m} symbols. Bₗ represents the random variable version of bₗ. For example, FIG. 6 illustrates an example of quadrature amplitude modulation (QAM) with constellation size 16 and Gray labeling according to an embodiment of the disclosure. In the sequel, bit level l∈{0, 1, . . . , m−1} represents the position of Ith bit in the labeling.

Although FIG. 6 illustrates one example of a constellation and labeling rule for use in decoding of low-density parity check codes, various changes may be made to FIG. 6. For example, while FIG. 6 shows each symbol as represented with four bits (i.e., QAM16), six bits per symbol (QAM64) or eight bits per symbol (QAM256) may be employed instead.

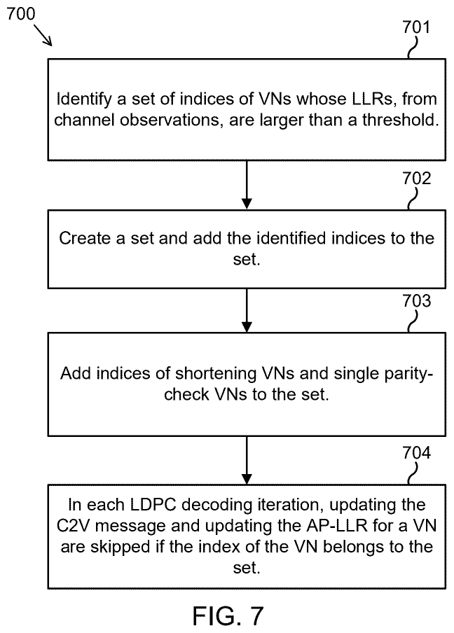

FIG. 7 is a flowchart of an example procedure 700 for decoding of low-density parity check codes according to embodiments of the present disclosure. For example, the procedure 700 for decoding of low-density parity check codes can be performed by the UE 116, the gNB 102, and/or network 130 in the wireless network 100 of FIG. 1. This example is for illustration only and other embodiments can be used without departing from the scope of the present disclosure.

In LDPC codes, there may exist shortening VNs whose corresponding bits are fixed to zeros and indices are known by the decoder. The bits corresponding to the shortening VNs may not be transmitted and their LLRs can be initialized to infinity for decoding. There may also exist single-parity-check (SPC) VNs which only have one neighboring CN.

The process 700 begins with identifying a second of indices for VNs whose LLRs from channel observations are larger than a threshold (step 701). Selection of a suitable threshold is described in further detail below. VNs with corresponding LLRs, calculated based on channel observations, have amplitudes larger than the threshold are identified and the respective indices form a set [symbol] ₀ (step 702). An example of identifying a set of VN indices is described in further detail below. For example, a set [symbol] is created and the set [symbol] ₀ of the identified indices are added to the set [symbol] . A set [symbol] ₁ of indices of shortening VNs and a set [symbol] ₂ of indices of SPC VNs are added to the set [symbol] (step 703). Following steps 702 and 703, [symbol] = [symbol] ₀∪ [symbol] ₁∪ [symbol] ₂. LDPC decoding is then performed, where C2V and V2C messages are updated (step 704). In each iteration, updating the C2V LLR and updating the AP-LLR for a VN are skipped if the index of the VN belongs to the set [symbol] . An example of LDPC decoding is described in further detail below.

Although FIG. 7 illustrates one example of a process 700 for decoding of low-density parity check codes, various changes may be made to FIG. 7. For example, while shown as a series of steps, various steps in FIG. 7 could overlap, occur in parallel, occur in a different order, or occur any number of times (including zero times).

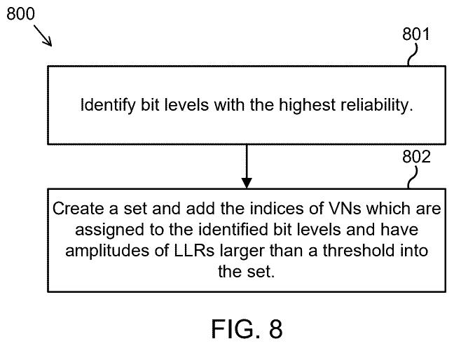

FIG. 8 is a flowchart of an example procedure 800 for identifying a set of indices of variable nodes according to embodiments of the present disclosure. For example, the procedure 800 for identifying a set of indices of variable nodes can be performed by the UE 116, the gNB 102, and/or network 130 in the wireless network 100 of FIG. 1, as part of the procedure 700 depicted in FIG. 7. This example is for illustration only and other embodiments can be used without departing from the scope of the present disclosure.

The process of FIG. 8 depicts one embodiment corresponding to step 701 in FIG. 7, to identify a set of VN indices. Without loss of generality, it is assumed that codeword bit vᵢ of LDPC codes is assigned to bit level l=(i mod m) in modulation with constellation size 2^{m}.

In the process 800, the bit levels with the highest reliability are identified (step 801), and the indices of the identified bit levels form a set [symbol] . In an embodiment, the reliability of a bit level can be measured by the mutual information between Bₗ and the received signal Y, denoted I(Bₗ,Y). The larger the mutual information is, the more reliable the bit level is. For example, in 16-QAM shown in FIG. 6, I(B₀,Y)=I(B₂,Y)>I(B₁,Y)=I(B₃,Y) and therefore the bit levels [symbol] ={0,2} can be identified. In another embodiment, the reliability of bit level l can be measured by the bit error rate Pₑ^{(l)}. The lower the bit error rate, the more reliable the bit level. Pₑ^{(l)} can be obtained as follows. Let ζ^{(l)} and s denote the LLR of bₗ and signal-to-noise ratio (SNR), respectively. Based on λ^{(l)}, a bit 0 is recovered if λ^{(l)}≥0, otherwise a bit 1 is recovered. Let p(λ^{(l)}|bₗ=b,s) denote probability density function (PDF) of λ^{(l)} which can be obtained according to methods in [2]. An error happens when bₗ=0 (bₗ=1) is sent but λ^{(l)}<0 (λ^{(l)}≥0). Therefore, the bit error rate can be computed as follows:

$${P}_{e}^{( l )} = 0.5 \times {\int }_{- ∞}^{0} p ( {λ}^{( l )} \vert {b}_{l} = 0 , s ) d {λ}^{( l )} + 0.5 \times {\int }_{0}^{+ ∞} p ( {λ}^{( l )} \vert {b}_{l} = 1 , s ) d {λ}^{( l )} .$$

Let λᵢ denote the LLR for VN vᵢ, which can be obtained from channel observations. The indices of the VNs which are assigned to the identified bit levels and have the amplitudes of corresponding LLRs larger than a threshold ω may be selected to form the set [symbol] ₀ (step 802). That is, [symbol] ₀={i:(i mod m)∈ [symbol] and |λᵢ|>ω}. One embodiment of generating the threshold ω is described below.

Although FIG. 8 illustrates one example of a process 800 for identifying a set of indices of variable nodes, various changes may be made to FIG. 8. For example, while shown as a series of steps, various steps in FIG. 8 could overlap, occur in parallel, occur in a different order, or occur any number of times (including zero times).

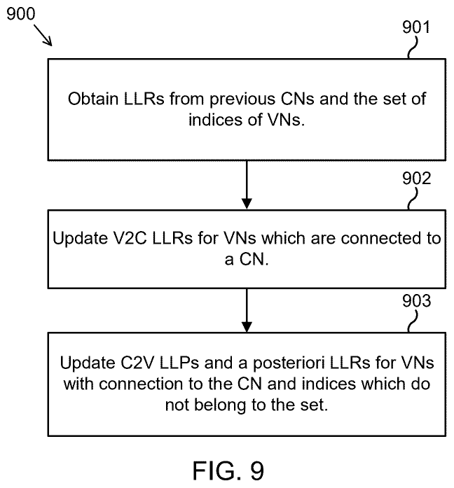

FIG. 9 is a flowchart of an example procedure 900 for check-node processing according to embodiments of the present disclosure. For example, the procedure 900 for check-node processing can be performed by the UE 116, the gNB 102, and/or network 130 in the wireless network 100 of FIG. 1, as part of the procedure 700 depicted in FIG. 7. This example is for illustration only and other embodiments can be used without departing from the scope of the present disclosure.

The process of FIG. 9 is one embodiment corresponding to step 704 to update messages when processing a CN. For the sake of simplicity, FIG. 8 only presented the operations concerning one CN and one iteration, which can be generalized to other CNs and iterations. Let Vⱼ and [symbol] ᵢ denote the set of indices of VNs connected to CN j and the set of indices of CNs connected to VN i, respectively. V_{j\i} and [symbol] _{i\j} denote Vⱼ excluding VN index i and [symbol] ᵢ excluding CN index j, respectively. α_{i→j} and β_{j→i} denote V2C message passed from VN i to CN j and C2V message passed from CN j to VN i, respectively. γᵢ denotes a posteriori LLR for VN vᵢ. β_{j→i} is initialized to zeros and γᵢ is initialized to λᵢ. Note that λᵢ for the shortening VNs is set as +∞.

In the process 900, the latest γᵢ and β_{j→i} due to the processing of previous CNs as well as the set [symbol] of VN indices according to step 701, step 702 and step 703 of FIG. 7 are obtained (step 901).

V2C LLRs for VNs connected to the CN j are updated (step 902) as follows:

$${α}_{i \to j} ← {γ}_{i} - {β}_{j \to i} for i ∈ {𝒱}_{j} .$$

C2V LLR and a posteriori LLR are updated (step 903) for a VN if the VN is connected to the CN j and the corresponding index does not belong to the set [symbol] . The updates are shown as follows:

$${β}_{j \to i} ← sgn ( {α}_{{i}^{′} \to j} ) \times f ( \{ \vert {α}_{{i}^{′} \to j} \vert : {i}^{′} ∈ {j ∖ i}_{} \} ) \qquad ( 1 )$$

$$and$$

$${γ}_{i} ← {α}_{i \to j} + {β}_{j \to i} , \qquad ( 2 )$$

for i∈Vⱼ∩{{0, 1, . . . , N−1}\ [symbol] }. In equation (1), sgn(⋅) returns the sign of a value and the function ƒ(⋅) depends on the methods used to calculate C2V LLR, e.g., in a min-sum algorithm

$$f ( \{ \vert {α}_{{i}^{′} \to j} \vert : {i}^{′} ∈ {j ∖ i}_{} \} ) = \vert {α}_{{i}^{′} \to j} \vert .$$

The updated γᵢ and β_{j→i} can be employed in the following CN processing and iterations.

Although FIG. 9 illustrates one example of a process 900 for check-node processing, various changes may be made to FIG. 9. For example, while shown as a series of steps, various steps in FIG. 9 could overlap, occur in parallel, occur in a different order, or occur any number of times (including zero times).

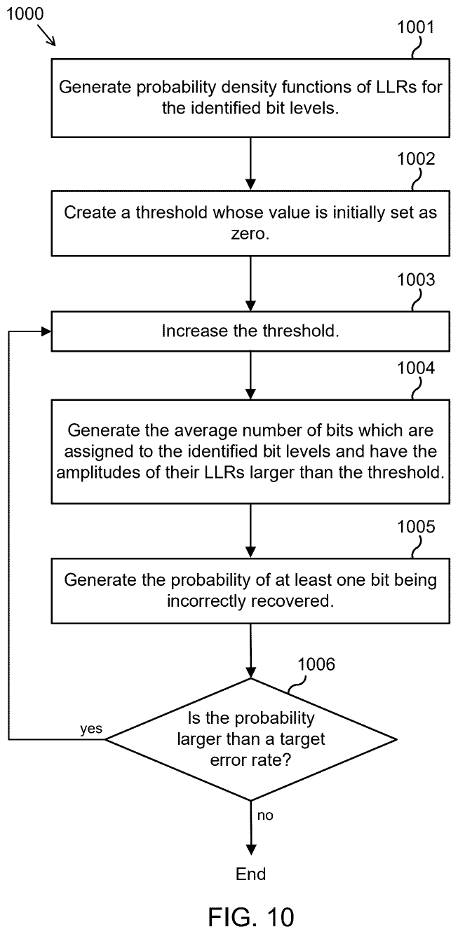

FIG. 10 is a flowchart of an example procedure 1000 for generating a threshold according to embodiments of the present disclosure. For example, the procedure 1000 for generating a threshold can be performed by the UE 116, the gNB 102, and/or network 130 in the wireless network 100 of FIG. 1, as part of the procedure 700 depicted in FIG. 7. This example is for illustration only and other embodiments can be used without departing from the scope of the present disclosure.

The process of FIG. 10 is one embodiment corresponding to step 802 to generate a threshold.

Let λ^{(l)} and s denote the LLR of bₗ and SNR, respectively. Given the value of the bit bₗ and the SNR of the channel, PDFs of λ^{(l)} for the identified bit levels (step 1001) are represented as follows:

$$p ( {λ}^{( l )} \vert {b}_{l} = b , s ) ,$$

where b∈{0,1} and l∈ [symbol] . A lookup table for p(λ^{(l)}|bₗ=b,s) can be obtained by using the methods in [2].

A threshold ω is created and with a value initially set as zero (step 1002), i.e., ω=0.

The threshold ω is increased by σ (step 1003), i.e., ω=ω+σ, where the value of σ can be small, for example 0.01.

The average number of bits which are assigned to the identified bit levels and have the amplitudes of their LLRs larger than the threshold is generated (step 1004) and denoted D. Given that the number of bits assigned to each level is

$$⌈ \frac{N}{m} ⌉ ,$$

D is calculated as follows:

$$D = ⌈ \frac{N}{m} ⌉ \times {\sum }_{l ∈ ℬ} {\sum }_{b ∈ \{ 0 , 1 \}} 0.5 \times [ {\int }_{- ∞}^{- ω} p ( {λ}_{l} \vert {b}_{l} = b , s ) d {λ}_{l} + {\int }_{ω}^{+ ∞} p ( {λ}_{l} \vert {b}_{l} = b , s ) d {λ}_{l} ] . \qquad ( 3 )$$

The probability of at least one bit being incorrectly recovered is generated (step 1005) as shown as follows:

$$P = 1 - {( 1 - P e )}^{D} ,$$

where Pe denotes the probability of a bit being wrongly recovered when assigned to the identified bit levels and the amplitude of the corresponding LLR is larger than the threshold ω. Pe is calculated as follows:

$$P e = \frac{1}{\vert ℬ \vert} {\sum }_{l ∈ ℬ} [ 0.5 \times {\int }_{- ∞}^{- ω} p ( {λ}^{( l )} \vert {b}_{l} = 0 , s ) d {λ}^{( l )} + 0.5 \times {\int }_{ω}^{+ ∞} p ( {λ}^{( l )} \vert {b}_{l} = 1 , s ) d {λ}^{( l )} ] . \qquad ( 4 )$$

If the resulting P in equation (4) is larger than a target error rate (step 1006), step 1003, step 1004 and step 1005 are repeated. Otherwise the operation is stopped and the final value of the threshold w is obtained. Note that by adjusting the target error rate, the final value of the threshold ω can be correspondingly adjusted. The value of the target error rate is not limited in the present disclosure.

Although FIG. 10 illustrates one example of a process 1000 for generating a threshold, various changes may be made to FIG. 10. For example, while shown as a series of steps, various steps in FIG. 10 could overlap, occur in parallel, occur in a different order, or occur any number of times (including zero times).

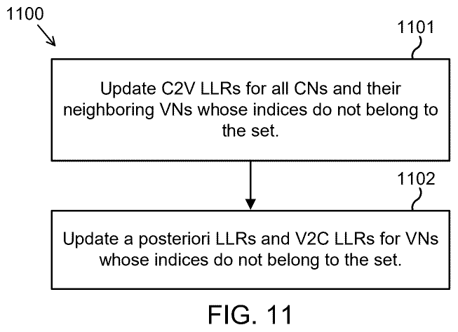

FIG. 11 is a flowchart of an example procedure 1100 for a single LDPC decoding iteration with flooding schedule according to embodiments of the present disclosure. For example, the procedure 1100 for a single LDPC decoding iteration with flooding schedule can be performed by the UE 116, the gNB 102, and/or network 130 in the wireless network 100 of FIG. 1, as part of the procedure 700 depicted in FIG. 7. This example is for illustration only and other embodiments can be used without departing from the scope of the present disclosure.

The process of FIG. 11 is one embodiment corresponding to step 704 to update messages. The process 1100 updates messages in a single LDPC decoding iteration with flooding schedule. However, FIG. 11 can be generalized to other iterations. Note that λᵢ for the shortening VNs is set as +∞. α_{i→j} is initialized to λᵢ. β_{j→i} are initialized to zeros.

C2V LLRs for all CNs and their neighboring VNs whose indices do not belong to the set are updated (step 1101). At CN j, the operation is shown as follows:

$${β}_{j \to i} ← sgn ( {α}_{{i}^{′} \to j} ) \times f ( \{ \vert {α}_{{i}^{′} \to j} \vert : {i}^{′} ∈ {j ∖ i}_{} \} ) for i ∈ {j}_{} ∩ \{ 0 , 1 , … , N - 1 \} ∖ 𝒮 .$$

The a posteriori LLRs and V2C LLRs for VNs whose indices do not belong to the set [symbol] are updated (step 1102). The a posteriori LLRs for VN i∈{0, 1, . . . , N−1}\ [symbol] is updated as follows:

$${γ}_{i} = {λ}_{i} + {β}_{j \to i} .$$

The V2C LLR passed from a VN i∈{0, 1, . . . , N−1}\ [symbol] to its neighboring CN j∈ [symbol] ᵢ is updated as follows:

$${α}_{i \to j} = {γ}_{i} - {β}_{j \to i} .$$

Although FIG. 11 illustrates one example of a process 1100 for a single LDPC decoding iteration with flooding schedule, various changes may be made to FIG. 11. For example, while shown as a series of steps, various steps in FIG. 11 could overlap, occur in parallel, occur in a different order, or occur any number of times (including zero times).

Referring back to FIG. 9, in another embodiment, V2C LLRs for VNs with connection to the CN j and indices which do not belong to the set are updated (step 902) as follows:

$${α}_{i \to j} ← {γ}_{i} - {β}_{j \to i} for i ∈ {j}_{} ∩ \{ \{ 0 , 1 , … , N - 1 \} ∖ \} .$$

For VN i∈Vⱼ∩ [symbol] , only the sign of γᵢ is passed to the CN j. The other operations can be identical or similar to the operations in the embodiment described above.

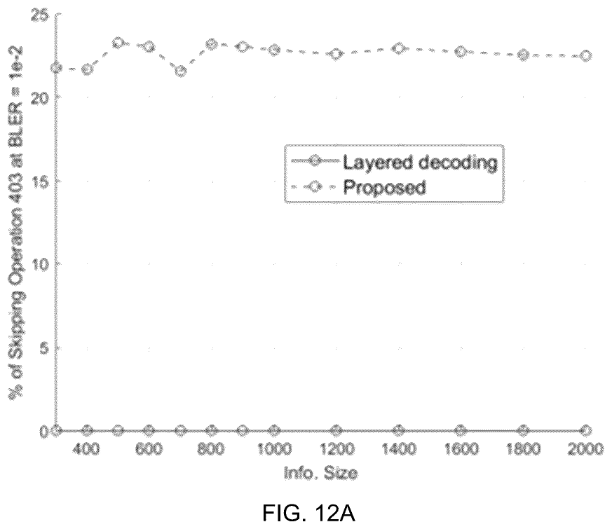

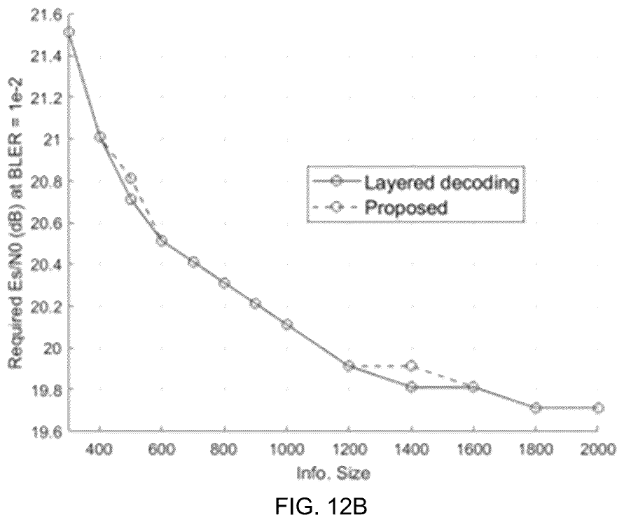

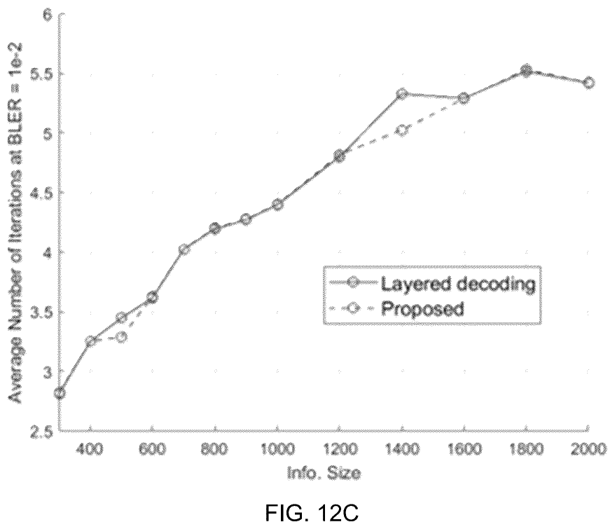

FIGS. 12A through 12C illustrate comparisons between decoding of low-density parity check codes without and with skipping the update of some messages in accordance with the present disclosure, in terms of block error rate (BLER), complexity, and average number of iterations. In all simulations, 5G NR LDPC codes, QAM256, and additive white Gaussian noise (AWGN) are applied. In addition, the code rate is 0.7 and the maximum number of iterations is 10. The target error rate is P=10⁻³. FIG. 12A shows over 20% reduction in the number of repetitions of operation 903 in FIG. 9, between decoding of low-density parity check codes without skipping update of some message (lower trace) and decoding of low-density parity check codes with skipping update of some message (upper trace), based on percent of skipping. FIGS. 12B and 12C, respectively, show that there is no significant loss in BLER and average number of iterations.

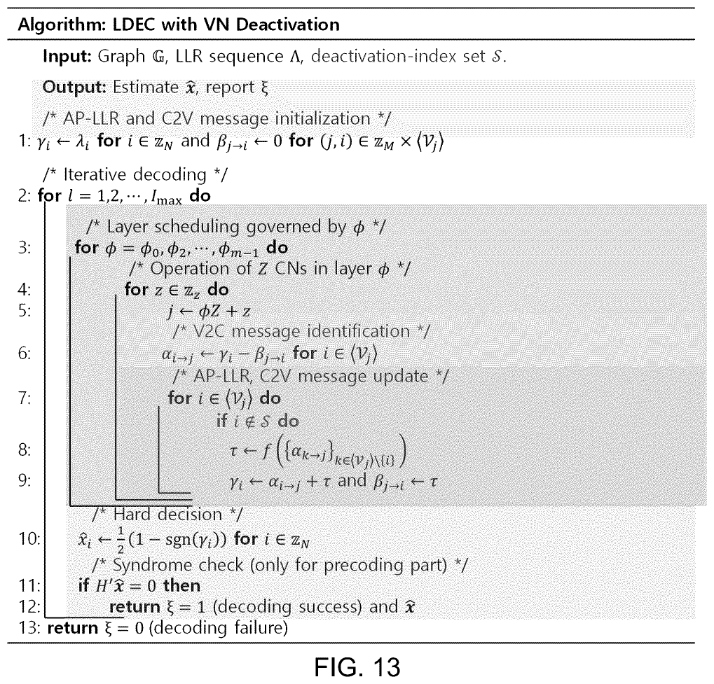

FIG. 13 shows pseudo-code for SW-LDEC with VN deactivation during decoding of low-density parity check codes in accordance with the present disclosure. The pseudo-code corresponds to step 704 in FIG. 7. With the pseudo-code shown, a set [symbol] ₀ of VNs with (absolute) initial LLRs larger than a threshold is identified, then [symbol] ₀ is combined with the set [symbol] ₁ of shortening VNs and the set [symbol] ₂ of SPC VNs to generate a deactivation set [symbol] = [symbol] ∪ [symbol] ₁∪ [symbol] ₂. The deactivation set S of VNs are determined prior to LDEC decoding. Deactivate operations (specifically steps 8 and 9 in the pseudo-code shown) corresponding to VNs belonging to [symbol] during CN processing are performed. One design of the threshold, and therefore the set [symbol] ₀, to get a good tradeoff between the complexity reduction and BLER loss is also shown. The threshold design considers both high order modulation and initial LLRs. In high-order modulation, bit levels have different reliabilities (in other words, bits have unequal error protections). The initial LLRs corresponding to bits assigned to most reliable levels tend to be large. Described at a high level the threshold design proceeds as follows:
Identify the set [symbol] of bit levels with highest reliability.
Calculate PDF of LLRs: p(λ^{(l)}|bₗ=b,s), where b∈{0,1} denotes the bit value assigned to a bit level and l∈ [symbol] denotes the bit level index.
Denote ω the threshold.
Calculate the average number of bits which are assigned to bit levels [symbol] and have their initial LLRs larger than the threshold: D(ω,p).
Calculate the probability of a bit being wrongly recovered when it is assigned to bit levels [symbol] and has an LLR larger than the threshold ω:Pe(ω,p).
The probability of at least one bit out of D bits being incorrectly recovered is shown as 1−(1−Pe)^{D}.
Hence, given a target error rate P which is a design parameter, the threshold @ is determined to be the smallest value satisfying 1−(1−Pe)^{D}≤P.

Any of the above variation embodiments can be utilized independently or in combination with at least one other variation embodiment. The above flowchart illustrates example methods that can be implemented in accordance with the principles of the present disclosure and various changes could be made to the methods illustrated in the flowchart herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the descriptions in this application should be read as implying that any particular element, step, or function is an essential element that must be included in the claims scope. The scope of patented subject matter is defined by the claims.

What is claimed is:

1. A method for decoding low-density parity check (LDPC) codes in a communication system, the method comprising:
identifying a first set of indices of variable nodes (VNs) having log-likelihood ratios (LLRs) greater than a threshold;
creating a second set of indices that includes the first set of indices, indices of shortening VNs, and indices of single parity check (SPC) VNs; and
performing LDPC decoding by iteratively updating check-to-variable (C2V) messages and variable-to-check (V2C) messages, wherein updates for a VN are skipped when an index of the respective VN belongs to the second set of indices.

2. The method of claim 1, wherein identifying the first set of indices of VNs comprises:
determining bit levels with the highest reliability based on mutual information between the bit levels and a received signal; and
selecting indices of VNs assigned to the determined bit levels whose LLRs are greater than the threshold.

3. The method of claim 2, wherein the threshold utilized for identifying the first set of indices of VNs is generated by:
(a) determining probability density functions (PDFs) of LLRs for the determined bit levels;
(b) creating a threshold value initially set to zero;
(c) calculating (i) an average number of bits assigned to the determined bit levels with LLRs larger than the threshold and (ii) a probability of at least one bit being incorrectly recovered;
(d) incrementally increasing the threshold value based on at least the probability of at least one bit being incorrectly recovered; and
iteratively repeating steps (c) and (d) until the probability of at least one bit being incorrectly recovered is less than a target error rate.

4. The method of claim 3, wherein the PDFs are determined using a lookup table.

5. The method of claim 3, wherein the average number of bits assigned to the determined bit levels with LLRs larger than the threshold is denoted D and the probability of at least one bit being incorrectly recovered is determined from
$$P = 1 - {( 1 - P e )}^{D} ,$$
where Pe denotes the probability of a bit being wrongly recovered when assigned to the determined bit levels.

6. The method of claim 1, wherein updating C2V messages is performed for all CNs for which an index of at least one neighboring VN belongs to the second set of indices, and wherein updating V2C messages is performed for VNs having an index belonging to the second set.

7. The method of claim 6, wherein updating a posteriori LLRs is performed for the VNs having an index belonging to the second set.

8. An apparatus for decoding low-density parity check (LDPC) codes in a communication system, the apparatus comprising:
a transceiver configured to receive a signal having an associated LDPC code; and
at least one processor coupled to the transceiver and configured to decode the LDPC code by:
identifying a first set of indices of variable nodes (VNs) having log-likelihood ratios (LLRs) greater than a threshold,
creating a second set of indices that includes the first set of indices, indices of shortening VNs, and indices of single parity check (SPC) VNs, and
performing LDPC decoding by iteratively updating check-to-variable (C2V) messages and variable-to-check (V2C) messages, wherein updates for a VN are skipped when an index of the respective VN belongs to the second set of indices.

9. The apparatus of claim 8, wherein identifying the first set of indices of VNs comprises:
determining bit levels with the highest reliability based on mutual information between the bit levels and a received signal; and
selecting indices of VNs assigned to the determined bit levels whose LLRs are greater than the threshold.

10. The apparatus of claim 9, wherein the threshold utilized for identifying the first set of indices of VNs is generated by:
(a) determining probability density functions (PDFs) of LLRs for the determined bit levels;
(b) creating a threshold value initially set to zero;
(c) calculating (i) an average number of bits assigned to the determined bit levels with LLRs larger than the threshold and (ii) a probability of at least one bit being incorrectly recovered;
(d) incrementally increasing the threshold value based on at least the probability of at least one bit being incorrectly recovered; and
iteratively repeating steps (c) and (d) until the probability of at least one bit being incorrectly recovered is less than a target error rate.

11. The apparatus of claim 10, wherein the PDFs are determined using a lookup table.

12. The apparatus of claim 10, wherein the average number of bits assigned to the determined bit levels with LLRs larger than the threshold is denoted D and the probability of at least one bit being incorrectly recovered is determined from
$$P = 1 - {( 1 - P e )}^{D} ,$$
where Pe denotes the probability of a bit being wrongly recovered when assigned to the determined bit levels.

13. The apparatus of claim 8, wherein updating C2V messages is performed for all CNs for which an index of at least one neighboring VN belongs to the second set of indices, and wherein updating V2C messages is performed for VNs having an index belonging to the second set.

14. The apparatus of claim 13, wherein updating a posteriori LLRs is performed for the VNs having an index belonging to the second set.

15. A non-transitory machine readable medium comprising instructions that, when executed by at least one processor of an electronic device, cause the electronic device to:
identify a first set of indices of variable nodes (VNs) having log-likelihood ratios (LLRs) greater than a threshold,
create a second set of indices that includes the first set of indices, indices of shortening VNs, and indices of single parity check (SPC) VNs, and
perform low-density parity check (LDPC) decoding by iteratively updating check-to-variable (C2V) messages and variable-to-check (V2C) messages, wherein updates for a VN are skipped when an index of the respective VN belongs to the second set of indices.

16. The non-transitory machine readable medium of claim 15, wherein identifying the first set of indices of VNs comprises:
determining bit levels with the highest reliability based on mutual information between the bit levels and a received signal; and
selecting indices of VNs assigned to the determined bit levels whose LLRs are greater than the threshold.

17. The non-transitory machine readable medium of claim 16, wherein the threshold utilized for identifying the first set of indices of VNs is generated by:
(a) determining probability density functions (PDFs) of LLRs for the determined bit levels;
(b) creating a threshold value initially set to zero;
(c) calculating (i) an average number of bits assigned to the determined bit levels with LLRs larger than the threshold and (ii) a probability of at least one bit being incorrectly recovered;
(d) incrementally increasing the threshold value based on at least the probability of at least one bit being incorrectly recovered; and
iteratively repeating steps (c) and (d) until the probability of at least one bit being incorrectly recovered is less than a target error rate.

18. The non-transitory machine readable medium of claim 17, wherein the PDFs are determined using a lookup table.

19. The non-transitory machine readable medium of claim 17, wherein the average number of bits assigned to the determined bit levels with LLRs larger than the threshold is denoted D and the probability of at least one bit being incorrectly recovered is determined from
$$P = 1 - {( 1 - P e )}^{D} ,$$
where Pe denotes the probability of a bit being wrongly recovered when assigned to the determined bit levels.

20. The non-transitory machine readable medium of claim 15, wherein updating C2V messages is performed for all CNs for which an index of at least one neighboring VN belongs to the second set of indices, and wherein updating V2C messages is performed for VNs having an index belonging to the second set.
